(19) United States
(12) Patent Application Publication
(10) Pub. No.: US 2017/0077387 A1
(43) Pub. Date: Mar. 16, 2017

(54) MAGNETIC TUNNEL JUNCTION (MTJ) DEVICES PARTICULARLY SUITED FOR EFFICIENT SPIN-TORQUE-TRANSFER (STT) MAGNETIC RANDOM ACCESS MEMORY (MRAM) (STT MRAM)

(71) Applicant: QUALCOMM Incorporated, San Diego, CA (US)

(72) Inventors: Jimmy Jianan Kan, San Diego, CA (US); Matthias Georg Gottwald, Leuven (BE); Xiaochun Zhu, San Diego, CA (US); Chando Park, Irvine, CA (US); Seung Hyuk Kang, San Diego, CA (US)

(21) Appl. No.: 14/856,372

(22) Filed: Sep. 16, 2015

(51) Int. Cl. H01L 43/02; H01L 43/12

(52) U.S. Cl. CPC H01L 43/02; H01L 43/12

(57) ABSTRACT

Magnetic Tunnel Junction (MTJ) devices particularly suited for efficient spin-torque-transfer (STT) magnetic random access memory (MRAM) (STT MRAM) are disclosed. In one aspect, a MTJ structure with a reduced thickness first pinned layer provided below a tunnel magneto-resistance (TMR) barrier layer is provided. The first pinned layer provided below the TMR bather layer includes one pinned layer magnetized in only one magnetic orientation. In another aspect, a second pinned layer and a spacer layer are provided above a free layer and the TMR barrier layer in the MTJ. The second pinned layer is magnetized in a magnetic orientation that is anti-parallel to that of the first pinned layer. In yet another aspect, a giant magneto-resistance (GMR) spacer layer is provided as the spacer layer between the second pinned layer and the free layer in the MTJ.

### BACKGROUND

I. Field of the Disclosure

The technology of the disclosure relates generally to the structure of magnetic tunnel junction (MTJ) devices that can be used, for example, in magnetic random access memory (MRAM).

II. Background

Semiconductor storage devices are used in integrated circuits (ICs) in electronic devices to provide data storage. One example of a semiconductor storage device is a magnetic random access memory (MRAM). MRAM is non-volatile memory in which data is stored by programming a magnetic tunnel junction (MTJ) as part of a MRAM bit cell. One advantage of a MRAM is that MTJs in MRAM bit cells can retain stored information even when power is turned off. Data is stored in the MTJ as a small magnetic element rather than as an electric charge or current.

In this regard, FIG. 1 is an illustration of a MTJ 100 provided in a MRAM bit cell to store data as a function of magnetization directions of two (2) layers in the MTJ 100. Data is stored in the MTJ 100 according to the magnetic orientation between two layers: a free layer 102 disposed above a pinned layer 104. In the MTJ 100, the free and pinned layers 102, 104 are formed from a ferromagnetic material with perpendicular magnetic anisotropy (i.e., the magnetization direction is perpendicular to a layer plane), to form a perpendicular MTJ (pMTJ). The MTJ 100 is configured in a “bottom-spin valve” configuration wherein the pinned layer 104 is disposed below the free layer 102. The free and pinned layers 102, 104 are separated by a tunnel junction or tunnel barrier layer 106, formed by a thin non-magnetic dielectric layer. The free and pinned layers 102, 104 can store information even when the magnetic H-field is ‘0’ due to a hysteresis loop 108 of the MTJ 100. Electrons can tunnel through the tunnel barrier layer 106 if a bias voltage is applied between two electrodes 110, 112 coupled on ends of the MTJ 100. The tunneling current depends on the relative orientation of the free and pinned layers 102, 104. When using a spin-torque-transfer (STT) MTJ (not shown), the difference in the tunneling current as the spin alignment of the free and pinned layers 102, 104 is switched between being parallel (P) and anti-parallel (AP) is known as a tunnel magneto-resistance (TMR) ratio.

When the magnetic orientation of the free and pinned layers 102, 104 is AP (shown in FIG. 1 as MTJ 100′), a first memory state exists (e.g., a logical ‘1’) (also referred to herein as “AP state”). When the magnetic orientation of the free and pinned layers 102, 104 is P (shown in FIG. 1 as MTJ 100″), a second memory state exists (e.g., a logical ‘0’) (also referred to herein as “P state”). The magnetic orientation of the free and pinned layers 102, 104 can be detected in order to read data stored in the MTJ 100 by sensing the resistance when current flows through the MTJ 100. Data can be written and stored in the MTJ 100 by applying a magnetic field or electrical current to change the magnetic orientation of the free layer 102 to either a P or AP magnetic orientation with respect to the pinned layer 104. The magnetic orientation of the free layer 102 can be changed, but the magnetic orientation of the pinned layer 104 is fixed.

When reading data stored in the MTJ 100, a read voltage differential is applied between the electrodes 110, 112 to allow current to flow through the MTJ 100. A low resistance, as measured by a voltage differential between the electrodes 110, 112 divided by a measured current, is associated with a P magnetic orientation between the free and pinned layers 102, 104, and thus, the MTJ 100 is considered as being in a P state. A high resistance is associated with an AP magnetic orientation between the free and pinned layers 102, 104, and thus, the MTJ 100 is considered as being in an AP state. When writing data to the MTJ 100, a write voltage differential is applied between the electrodes 110, 112 to generate a write current through the MTJ 100. If the state of the MTJ 100 is to be changed from a P state to an AP state, a write current (I_{P-AP}) flowing from the bottom electrode 112 to the top electrode 110 is produced to induce a STT at the free layer 102 to change the magnetic orientation of the free layer 102 to be AP with respect to the pinned layer 104. This is shown by the MTJ 100′ in FIG. 1. If, on the other hand, the state is to be changed from an AP state to a P state, a write current (I_{AP-P}) flowing from the top electrode 110 to the bottom electrode 112 is generated to induce a STT at the free layer 102 to change the magnetic orientation of the free layer 102 to be P with respect to the pinned layer 104. This is shown by the MTJ 100″ in FIG. 1.

FIG. 2 is a schematic diagram illustrating the magnetization of a MTJ 200. The MTJ 200 includes a MTJ stack structure 202 that can be employed in the MTJ 100 in FIG. 1. The MTJ stack structure 202 includes a bottom electrode 204, a pinned layer 206, an anti-ferromagnetically coupled (AFC) spacer layer 208, a polarization enhancing layer 209, a tunnel magneto-resistance (TMR) barrier layer 210, a free layer 212, and a top electrode 214. In the MTJ stack structure 202, the magnetic orientation of the pinned layer 206 is fixed. Accordingly, the pinned layer 206 generates a constant magnetic field that may affect, or “bias,” a magnetic orientation of the free layer 212. This magnetic field bias, at best, can cause an asymmetry in the magnitude of current necessary to change the magnetic orientation of the free layer 212 (i.e., I_{P-AP} is different than I_{AP-P}). The current necessary to change the magnetic orientation towards the bias orientation is reduced while the current necessary to change the magnetic orientation of the free layer 212 against the bias is increased. At worst, this magnetic field bias can be strong enough to “flip” the value of a memory bit cell employing the MTJ 200 in FIG. 2, thus decreasing the reliability of the subject MRAM. In this regard, the pinned layer 206 includes a synthetic anti-ferromagnetic (SAF) structure 216, wherein the pinned layer 206 includes a first anti-parallel layer AP1 and a second anti-parallel layer AP2. These first and second anti-parallel layers AP1, AP2 are permanently magnetized and magnetically coupled in opposite orientations to generate opposing magnetic fields. The opposite magnetic fields produce a zero or near-zero net magnetic field towards the free layer 212, thus reducing the magnetic field bias problem at the free layer 212.

Because the SAF structure 216 of the MTJ 200 in FIG. 2 that forms the pinned layer 206 requires the first and second anti-parallel layers AP1, AP2 below the TMR barrier layer 210, this can make the pinned layer 206 below the TMR barrier layer 210 thicker. Specifically, each of the first and second anti-parallel layers AP1, AP2 can include multiple layers (e.g., a Cobalt (Co)-Platinum (Pt)-Cobalt (Co) film) that each require a minimum thickness to be effective. During fabrication, imperfections or variations due to uneven deposition of materials across the planes of the layers can propagate through the structure as material layers forming the anti-parallel layers AP1, AP2, thus creating a “rough” surface at a base 218 of the TMR barrier layer 210. The thicker the area under the TMR barrier layer 210, the more likely “roughness” will be present at the base 218 of the TMR barrier layer 210. Because the TMR barrier layer 210 is a relatively thin layer (e.g., 5-10 angstroms), roughness at the base 218 of the TMR barrier layer 210 may degrade the functionality of the MTJ 200 by reducing the MTJ 200 TMR ratio.

### SUMMARY OF THE DISCLOSURE

Aspects disclosed in the detailed description include magnetic tunnel junction (MTJ) devices particularly suited for efficient spin-torque-transfer (STT) magnetic random access memory (MRAM) (STT MRAM). In this manner, unevenness or roughness at the junction between the pinned layer and the TMR layer, which can be caused by propagated imperfections or variations in the pinned layer fabrication process, can be reduced to avoid reducing a TMR ratio of the TMR layer. In this regard, in certain exemplary aspects disclosed herein, a pinned layer section in a MTJ that is provided below the TMR layer includes one pinned layer magnetized in only one magnetic orientation. However, providing only one pinned layer magnetized in one magnetic orientation below the TMR layer can bias a magnetic orientation of a free layer disposed above the TMR layer in the magnetic orientation of the pinned layer, thus reducing the reliability and/or the usability of the corresponding MTJ. In this regard, in other exemplary aspects disclosed herein, a second pinned layer and a spacer layer are disposed above the free layer and the TMR layer in the MTJ. The second pinned layer is magnetized in a magnetic orientation that is anti-parallel (AP) to that of the pinned layer disposed below the TMR layer. This configuration reduces the net magnetic field (i.e., bias) on the free layer from the pinned layer disposed below the TMR layer. This configuration also provides a more efficient spin torque polarization when switching between a parallel (P) state and an anti-parallel (AP) state, which results in reduced overall write current and reduced write current asymmetry. This configuration is also scalable with size as MTJ diameter is reduced without substantial engineering of materials and/or corresponding thicknesses.

Although the spacer layer in a MTJ structure can be a second TMR layer, in certain other exemplary aspects, the resistance of such a second TMR layer can be made to differ from the resistance of a first TMR layer, between the free layer and the one pinned layer, in order to switch the magnetic orientation of the free layer. Thus, in exemplary aspects disclosed herein, a giant magneto-resistance (GMR) spacer layer is also disposed between the second pinned layer and the free layer as the spacer layer in the MTJ. The GMR spacer layer provides functionality similar to that of the TMR layer, but because the GMR spacer layer is a conducting layer made of conductive material, the resistance of the GMR spacer layer can be reduced to less than the resistance of the TMR layer. For example, the GMR spacer layer provides a barrier layer that is simple to achieve and that includes a resistance that can be reliably controlled. Having reliable control of the resistance of the GMR spacer layer, and in particular, of the difference between the resistances of the TMR layers and the GMR spacer layer, allows for a more reliable and discernable resistive output to be sensed from the MTJ. Furthermore, conductive materials used for the GMR spacer layer may be easier to deposit and etch in a MTJ than the materials used for a TMR layer.

In this regard in one aspect, a MTJ is provided. The MTJ comprises a first electrode, a second electrode, and a tunnel barrier layer disposed between the first electrode and the second electrode. The tunnel barrier layer is configured to provide a first magneto-resistance between a first pinned layer and a free layer when the first pinned layer is anti-parallel to the free layer. The first pinned layer is disposed between the tunnel barrier layer and the first electrode, and is configured to provide a first magnetization only in a first direction between the tunnel barrier layer and the first electrode. The MTJ further comprises a second pinned layer disposed between the second electrode and the tunnel barrier layer. The second pinned layer is configured to provide a second magnetization in a second direction that is anti-parallel to the first direction. The free layer is disposed between the second pinned layer and the tunnel barrier layer. The MTJ further comprises a spacer layer disposed between the second pinned layer and the free layer. The spacer layer is configured to provide a second magneto-resistance between the second pinned layer and the free layer when the second pinned layer is anti-parallel to the free layer.

In another aspect, a method of forming a MTJ is provided. The method comprises providing a first electrode and a second electrode, placing a tunnel barrier layer between the first electrode and the second electrode, and placing a first pinned layer between the tunnel barrier layer and the first electrode. The method further comprises placing a second pinned layer between the second electrode and the tunnel barrier layer, placing a free layer between the second pinned layer and the tunnel barrier layer, and placing a spacer layer between the second pinned layer and the free layer.

In another aspect, a MRAM bit cell is provided. The MRAM bit cell comprises an access transistor, which has a gate, a source, and a drain. The MRAM bit cell further comprises a MTJ. The MTJ comprises a first electrode and a second electrode, and a tunnel barrier layer that is disposed between the first electrode and the second electrode. The tunnel barrier layer is configured to provide a first magneto-resistance between a first pinned layer and a free layer when the first pinned layer is anti-parallel to the free layer. The first pinned layer is disposed between the tunnel barrier layer and the first electrode, and is configured to provide a first magnetization only in a first direction between the tunnel barrier layer and the first electrode. The MTJ further comprises a second pinned layer that is disposed between the second electrode and the tunnel barrier layer, and is configured to provide a second magnetization in a second direction that is anti-parallel to the first direction. The free layer is disposed between the second pinned layer and the tunnel barrier layer. The MTJ further comprises a spacer layer that is disposed between the second pinned layer and the free layer, and is configured to provide a second magneto-resistance between the second pinned layer and the free layer when the second pinned layer is anti-parallel to the free layer. In the MRAM bit cell, a word line is coupled to the gate, the second electrode is coupled to the drain, and a bit line is coupled to the first electrode.

In another aspect, a MTJ is provided. The MTJ comprises a first electrode and a second electrode. The MTJ further comprises a tunnel barrier layer disposed between the first electrode and the second electrode. The tunnel barrier layer comprises Magnesium Oxide (MgO). The MTJ further comprises a first pinned layer disposed between the tunnel barrier layer and the first electrode. The first pinned layer comprises Cobalt (Co) and at least one of Platinum (Pt), Nickel (Ni), and Palladium (Pd). The first pinned layer is configured to provide a first magnetization only in a first direction between the tunnel barrier layer and the first electrode. The MTJ further comprises a second pinned layer disposed between the second electrode and the tunnel barrier layer. The second pinned layer is configured to provide a second magnetization in a second direction that is anti-parallel to the first direction. The MTJ further comprises a free layer disposed between the second pinned layer and the tunnel barrier layer. The free layer comprises Cobalt (Co), Iron (Fe), and Boron (B).

### BRIEF DESCRIPTION OF THE FIGURES

FIG. 1 is an illustration of a perpendicular magnetic tunnel junction (MTJ) provided in a MRAM bit cell to store data as a function of magnetization directions of a pinned layer and a free layer in the MTJ;

FIG. 2 is a schematic diagram illustrating magnetization of a MTJ;

FIG. 3 is a schematic diagram of an exemplary MTJ that includes a reduced thickness pinned layer provided by a tunnel magneto-resistance (TMR) layer to reduce unevenness or roughness at a junction between the TMR layer and the pinned layer to avoid reducing a TMR ratio of the TMR layer;

FIG. 4 is an graph illustrating a write current applied to the MTJ in FIG. 1 to write a memory state into the MTJ;

FIG. 5 is a schematic diagram illustrating the magnetization of an exemplary MTJ stack structure illustrated in FIG. 3, under an anti-parallel state and a parallel state;

FIG. 6 is a schematic diagram illustrating a detailed stack structure of the exemplary MTJ illustrated in FIG. 3;

FIG. 7 is a schematic diagram illustrating exemplary dimensions for the exemplary MTJ illustrated in FIG. 3;

FIG. 8 is a schematic diagram of a MRAM bit cell that includes a a MTJ similar to the exemplary MTJ illustrated in FIG. 3; and

FIG. 9 is a block diagram of an exemplary processor-based system that can include the exemplary MTJ illustrated in FIG. 3.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include magnetic tunnel junction (MTJ) devices particularly suited for efficient spin-torque-transfer (STT) magnetic random access memory (MRAM) (STT MRAM). In this manner, unevenness or roughness at the junction between the pinned layer and the TMR layer, which can be caused by propagated imperfections or variations in the pinned layer fabrication process, can be reduced to avoid reducing a TMR ratio of the TMR layer. In this regard, in certain exemplary aspects disclosed herein, a pinned layer section in a MTJ that is provided below the TMR layer includes one pinned layer magnetized in only one magnetic orientation. However, providing only one pinned layer magnetized in one magnetic orientation below the TMR layer can bias a magnetic orientation of a free layer disposed above the TMR layer in the magnetic orientation of the pinned layer, thus reducing the reliability and/or the usability of the corresponding MTJ. In this regard, in other exemplary aspects disclosed herein, a second pinned layer and a spacer layer are disposed above the free layer and the TMR layer in the MTJ. The second pinned layer is magnetized in a magnetic orientation that is anti-parallel (AP) to that of the pinned layer disposed below the TMR layer. This configuration reduces the net magnetic field (i.e., bias) on the free layer from the pinned layer disposed below the TMR layer. This configuration also provides a more efficient spin torque polarization when switching between a parallel (P) state and an anti-parallel (AP) state, which results in reduced overall write current and reduced write current asymmetry. This configuration is also scalable with size as MTJ diameter is reduced without substantial engineering of materials and/or corresponding thicknesses.

Although the spacer layer in a MTJ structure can be a second TMR layer, in certain other exemplary aspects, the resistance of such a second TMR layer can be made to differ from the resistance of a first TMR layer, between the free layer and the one pinned layer, in order to switch the magnetic orientation of the free layer. Thus, in exemplary aspects disclosed herein, a giant magneto-resistance (GMR) spacer layer is also disposed between the second pinned layer and the free layer as the spacer layer in the MTJ. The GMR spacer layer provides functionality similar to that of the TMR layer, but because the GMR spacer layer is a conducting layer made of conductive material, the resistance of the GMR spacer layer can be reduced to less than the resistance of the TMR layer. For example, the GMR spacer layer provides a barrier layer that is simple to achieve and that includes a resistance that can be reliably controlled. Having reliable control of the resistance of the GMR spacer layer, and in particular, of the difference between the resistances of the TMR layers and the GMR spacer layer, allows for a more reliable and discernable resistive output to be sensed from the MTJ. Furthermore, conductive materials used for the GMR spacer layer may be easier to deposit and etch in a MTJ than the materials used for a TMR layer.

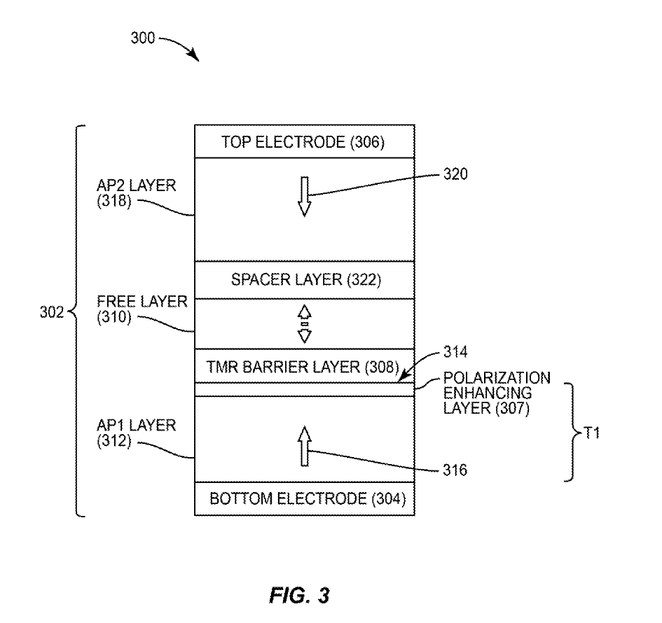

In this regard, FIG. 3 is a schematic diagram illustrating the magnetization of an exemplary MTJ 300 that includes a reduced thickness pinned layer provided by a TMR layer to reduce unevenness or roughness at a junction between the TMR layer and the pinned layer to avoid reducing a TMR ratio of the TMR layer. In this regard, as shown in FIG. 3, the MTJ 300 includes an exemplary MTJ stack structure 302. The MTJ stack structure 302 includes a bottom electrode 304 and a top electrode 306. The MTJ stack structure 302 further includes a polarization enhancing layer 307, a TMR barrier layer 308, and a free layer 310. The TMR barrier layer 308 is disposed between the bottom electrode 304 and the top electrode 306. The TMR barrier layer 308 comprises a non-conductive material that provides a first magneto-resistance that is a high magneto-resistance between a first pinned layer 312 of the MTJ stack structure 302, provided in the form of an AP pinned layer 312 (also referred to herein as “AP1 layer 312”), and the free layer 310, when the magnetic orientation of the AP1 layer 312 is AP to that of the free layer 310. This is due to a TMR effect created by the combination of the free layer 310, the TMR barrier layer 308, and the AP1 layer 312 within the MTJ stack structure 302. A TMR effect is a change in electrical resistance, by virtue of tunneling of electrons through the TMR barrier layer 308, depending on whether the magnetic orientation of the adjacent free layer 310 and the AP1 layer 312 are in a P or an AP alignment.

With continuing reference to FIG. 3, the MTJ stack structure 302 further includes the AP1 layer 312 disposed between the TMR barrier layer 308 and the bottom electrode 304. The AP1 layer 312 is configured to provide a true reference/fixed layer for the magneto-resistance functionality of the TMR barrier layer 308 between the AP1 layer 312 and the free layer 310. The AP1 layer 312 is configured to provide a first magnetization only in a first direction 316 between the TMR barrier layer 308 and the bottom electrode 304.

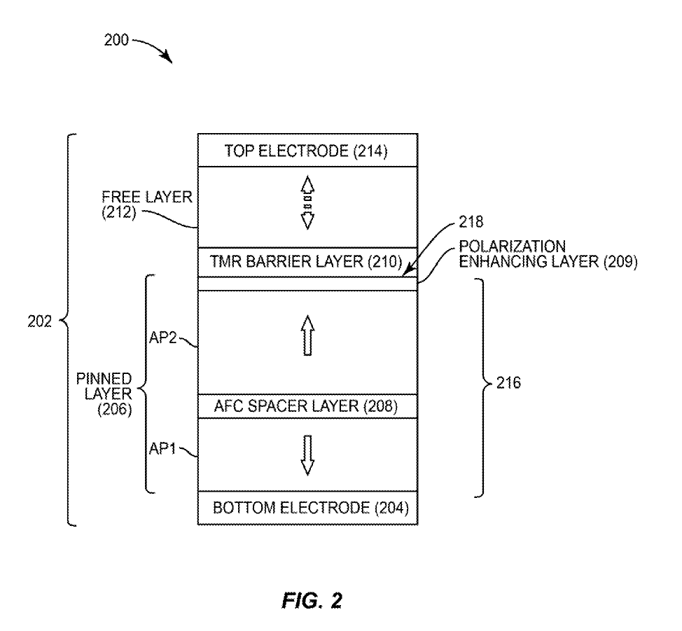

Having a pinned layer 312 section below the TMR barrier layer 308 in the MTJ 300 that includes only one AP pinned layer 312 (i.e., the AP1 layer 312) allows for a reduction of the thickness under the TMR barrier layer 308 relative to a MTJ stack structure that has two pinned layers disposed under a TMR barrier layer, such as in, for example, the MTJ stack structure 202 illustrated in FIG. 2. Including only one AP pinned layer 312 (i.e., the AP1 layer 312) in the MTJ stack structure 302 may reduce the probability and/or the degree of roughness at a base 314 of the TMR barrier layer 308, thus avoiding a reduction in a TMR ratio relative to that of the MTJ stack structure 202 in FIG. 2 as an example. This is because the thicker the area under the TMR barrier layer 308, the more likely “roughness” will be present at the base 314 of the TMR barrier layer 308. Roughness at the base 314 of the TMR barrier layer 308 may degrade the functionality of the TMR barrier layer 308 and, thus, reduce the TMR ratio of the MTJ stack structure 302. However, because the AP1 layer 312 is magnetized only in the first direction 316, the magnetic field of the AP1 layer 312 can bias the magnetic orientation of the free layer 310 in the first direction 316, thus reducing the reliability and/or the usability of the MTJ 300.

In this regard, the MTJ stack structure 302 in FIG. 3 includes a second pinned layer 318 provided in the form of an AP2 layer 318 disposed between the top electrode 306 and the TMR barrier layer 308. The free layer 310 is disposed between the AP2 layer 318 and the TMR barrier layer 308. The AP2 layer 318 is configured to provide a second magnetization in a second direction 320 that is anti-parallel to the first direction 316 in order to counter the magnetization in the first direction 316, balance the stray field emitted from the AP1 layer 312, and reduce the net magnetic field on the free layer 310 to zero or near-zero.

Accordingly, in the MTJ stack structure 302, a thickness T1 of the AP1 layer 312 below the TMR barrier layer 308 is less than in the pinned layer 206 structure provided below the TMR barrier layer 210 in the MTJ stack structure 202 in FIG. 2. This reduces the probability and/or the degree of roughness at the base 314 of the TMR barrier layer 308 while maintaining control over of the net magnetic field at the free layer 310 created by the AP1 layer 312.

Another aspect of the MTJ stack structure 302 in FIG. 3 is that, because the AP1 layer 312 and the AP2 layer 318 are disposed at a similar distance from the free layer 310, designing the AP1 layer 312 and the AP2 layer 318 to control the net magnetic field on the free layer 310, and to control any future scaling of the AP1 layer 312 and the AP2 layer 318, is easier than for the MTJ stack structure 202 illustrated in FIG. 2. In detail, in the MTJ stack structure 202 illustrated in FIG. 2, the anti-parallel layers AP1, AP2 are disposed below the TMR barrier layer 210. The anti-parallel layers AP1, AP2 are configured to generate zero or near-zero net magnetic field at the free layer 212. However, the magnitude of the magnetic field that each of the anti-parallel layers AP1, AP2 generates on the free layer 212 is a function of their respective size and distance from the free layer 212. As illustrated in FIG. 2, in the MTJ stack structure 202, the anti-parallel layer AP1 is located further away from the free layer 212 than the anti-parallel layer AP2. Therefore, determining the correct size of each of the anti-parallel layers AP1, AP2, as well as scaling the size of each of the anti-parallel layers AP1, AP2 for reducing the overall size of the MTJ stack structure 202, requires a complex redesign/readjustment of the size of each of the anti-parallel layers AP1, AP2.

In the MTJ stack structure 302 illustrated in FIG. 3, however, the AP1 layer 312 and the AP2 layer 318 are disposed at a similar distance from the free layer 310 (the AP1 layer 312 is below the free layer 310 and the AP2 layer 318 is above the free layer 310). Accordingly, determining the correct size of each of the AP1 layer 312 and the AP2 layer 318 to control the net magnetic field on the free layer 310, and for future scaling of the AP1 layer 312 and the AP2 layer 318, is easier than for the MTJ stack structure 202 illustrated in FIG. 2.

Furthermore, the AP2 layer 318 is disposed above the free layer 310 as part of a second magneto-resistive structure. In particular, the MTJ stack structure 302 further includes a spacer layer 322 disposed between the AP2 layer 318 and the free layer 310 to form the second magneto-resistive structure. The spacer layer 322 comprises a conductive material for conducting electrons, and their corresponding polarized spins, thus allowing for a GMR effect in the magneto-resistive structure comprised of the AP2 layer 318, the spacer layer 322, and the free layer 310 within the MTJ stack structure 302. The spacer layer 322 provides a second magneto-resistance in the MTJ stack structure that is a low magneto-resistance relative to the first magneto-resistance provided by the TMR barrier layer 308. The second magneto-resistance is provided between a first pinned layer 312 of the MTJ stack structure 302 (also referred to herein as “AP1 layer 312”), and the free layer 310, when the magnetic orientation of the AP1 layer 312 is AP to that of the free layer 310.

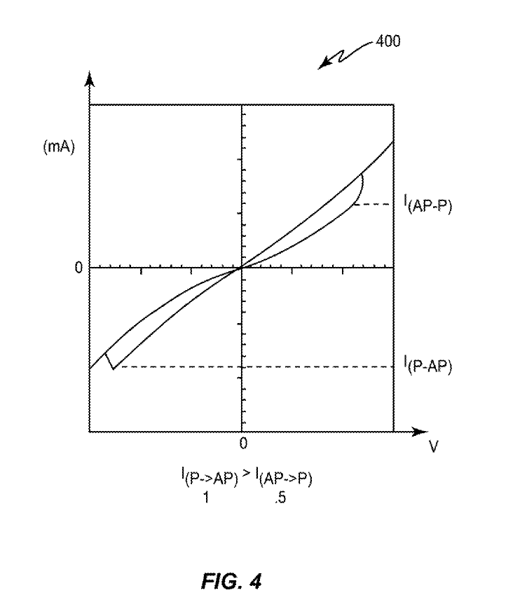

As will be described in further detail with reference to FIG. 4 below, having the AP2 layer 318 as part of a magneto-resistive structure increases the efficiency of switching the MTJ stack structure 302 from a parallel (P) state to an anti-parallel (AP) state and from an AP state to a P state.

With continuing reference to FIG. 3, the spacer layer 322 can be a second TMR layer, thus making the second magneto-resistive structure function according to a TMR effect. However, for the MTJ stack structure 302 to properly store data, the magneto-resistance of the spacer layer 322 cannot be similar to the magneto-resistance of the TMR barrier layer 308. In detail, if the magneto-resistance at the spacer layer 322 is similar to that of the TMR barrier layer 308, a voltage generated at the MTJ stack structure 302 in response to a read current when the MTJ stack structure 302 is in a P state will be substantially similar to a voltage generated at the MTJ stack structure 302 in response to a read current when the MTJ stack structure 302 is in an AP state. This is because, regardless of the orientation of the free layer 310, one of the TMR barrier layer 308 and the spacer layer 322 will have an adjacent pinned layer from the AP1 and AP2 layers 312, 318 parallel to the free layer 310, while the other will have an adjacent pinned layer from the AP1 and AP2 layers 312, 318 anti-parallel to the free layer 310. Thus, if the magneto-resistance at the spacer layer 322 is similar to the magneto-resistance at the TMR barrier layer 308, the orientation of the free layer 310 cannot be easily determined, and the data stored in the MTJ 300 will not be readable. On the other hand, if the magneto-resistance of the spacer layer 322 is different than the magneto-resistance provided by the TMR barrier layer 308, a voltage generated at the MTJ stack structure 302 in response to a read current when the MTJ stack structure 302 is in a P state will be substantially different to a voltage generated at the MTJ stack structure 302 in response to a read current when the MTJ stack structure 302 is in an AP state. Because fabricating and/or deposing the spacer layer 322 as a TMR barrier with a magneto-resistance that is different from the magneto-resistance of the TMR barrier layer 308 adds complexity to the MTJ 300, in an aspect of the disclosure, the spacer layer 322 comprises a GMR barrier layer, using a conductive material, which provides a lower magneto-resistance than a similarly deposed TMR barrier layer at a lower level of complexity.

Therefore, in the MTJ stack structure 302, the spacer layer 322 between the AP2 layer 318 and the free layer 310 comprises a conductive material. Such a spacer layer 322 provides a different magneto-resistance than the TMR barrier layer 308, which allows for data stored at the MTJ stack structure 302 to be read, and allows for the symmetrical structure of the MTJ stack structure 302, without adding design and/or fabrication complexity to the MTJ stack structure 302.

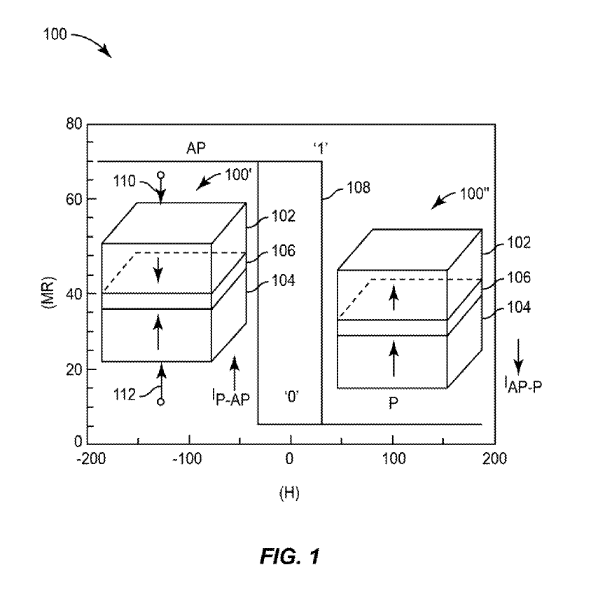

The MTJ stack structure 302 further provides a reduction of write current asymmetry by virtue of a more efficient spin-torque-transfer. In detail, the MTJ 100 illustrated in FIG. 1 inherently includes a level of write current asymmetry, i.e., the MTJ 100 requires more write current to switch from a P state to an AP state than from the AP state to the P state.

In this regard, FIG. 4 is a graph 400 illustrating a write current applied to the MTJ 100 in FIG. 1 to write a memory state into the MTJ 200. FIG. 4 will be described with reference to FIG. 1. The graph 400 illustrates that the amount of write current (I) required to switch the MTJ 100 from a P state to an AP state (I_{P-AP}) is much greater than the amount of I required to switch the MTJ 100 from an AP state to a P state (I_{AP-P}). This inherently occurs in MTJs, because of the process by which the spin torque of the electrons in the corresponding I is polarized. Specifically, given the pinned layer 104 with a net magnetic orientation in the “up” direction (as illustrated in FIG. 1 for the MTJ 100), when switching the MTJ 100 from an AP state to a P state (i.e., switching the magnetic orientation of the free layer 102 from the “down” direction to the “up” direction), I_{AP-P} flows from the bottom electrode 112 towards the top electrode 110. The electrons in I_{AP-P} become polarized in the “up” direction as they move through the pinned layer 104 and the tunnel barrier layer 106 towards the free layer 102. Because both the pinned and tunnel barrier layers 104, 106 contribute to the “up” polarization of the electrons, the polarization is generally efficient for switching the free layer 102 from the “down” polarization to the “up” polarization and, thus, the MTJ 100 from the AP state to the P state.

However, when switching the MTJ 100 from a P state to an AP state (i.e., switching the magnetic orientation of the free layer 102 from the “up” direction to the “down” direction), I_{P-AP} flows from the top electrode 110 towards the bottom electrode 112. The electrons in I_{P-AP} are not polarized in the “down” direction as they move through the free layer 102. The electrons in I_{P-AP} become polarized in the “down” direction only as they bounce/are reflected from the tunnel barrier layer 106, and only those electrons that bounce/are reflected from the tunnel barrier layer 106 contribute towards switching the magnetic orientation of the free layer 102 to the “down” direction. This process requires more electrons, and therefore is much less efficient, than when switching the magnetic orientation from the AP state to the P state. Accordingly, I_{P-AP} is larger than I_{AP-P}.

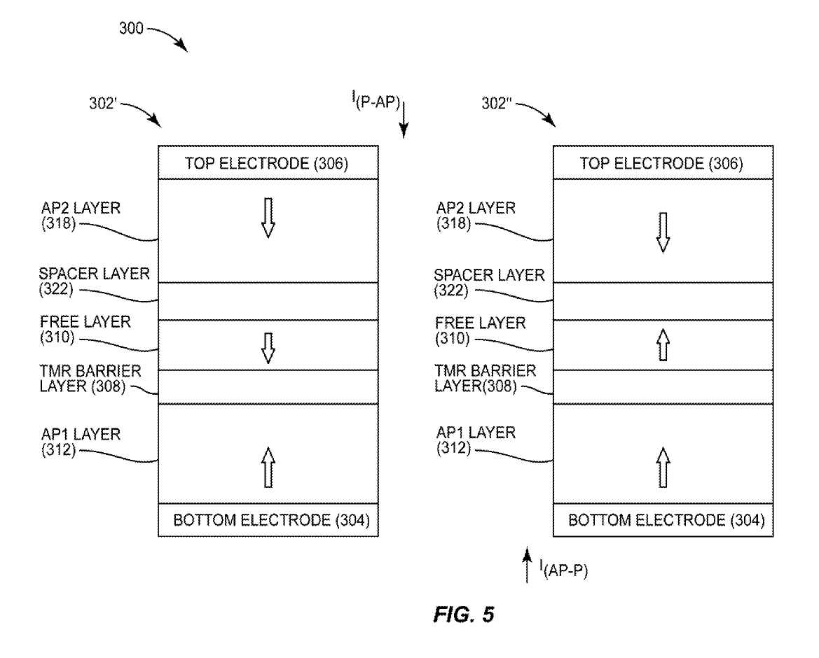

In this regard, FIG. 5 is a schematic diagram illustrating the magnetization of the exemplary MTJ stack structure 302 illustrated in FIG. 3, under an AP state 302′ and a P state 302″. If the combination of the AP1 layer 312 and the AP2 layer 318 have a net magnetic orientation in the “up” direction, when switching the MTJ stack structure 302 from the AP state 302′ to the P state 302″ (i.e., switching the magnetic orientation of the free layer 310 from the “down” direction to the “up” direction), I_{AP-P} flows from the bottom electrode 304 towards the top electrode 306. The electrons in I_{AP-P} become polarized in the “up” direction as they move through the AP1 layer 312 and the TMR barrier layer 308 towards the free layer 310. Because both the AP1 and the TMR barrier layers 312, 308 contribute to the “up” polarization of the electrons, the polarization is generally efficient for switching the free layer 310 from the “down” polarization to the “up” polarization, and thus, the MTJ stack structure 302 from the AP state 302′ to the P state 302″. The efficiency of switching the MTJ stack structure 302 from the AP state 302′ to the P state 302″ is therefore comparable to that of switching the MTJ 100 in FIG. 1 from the AP state to the P state.

However, when switching the MTJ stack structure 302 from the P state 302″ to the AP state 302′ (i.e., switching the magnetic orientation of the free layer 310 from the “up” direction to the “down” direction), I_{P-AP} flows from the top electrode 306 towards the bottom electrode 304. In the MTJ stack structure 302, contrary to the MTJ 100 in FIG. 1, the electrons in I_{P-AP} become polarized in the “down” direction as they move towards the free layer 310. Specifically, the electrons in I_{P-AP} become polarized in the “down” direction as they go through the AP2 layer 318. Furthermore, a conductive material of the spacer layer 322 does not significantly affect the polarization of the electrons, thus acting as a conductor for their polarized spins. Contrary to the MTJ 100 in FIG. 1, in the MTJ stack structure 302, the AP2 layer 318 provides an additional source of spin-polarization, and thus, enhances switching of the free layer 310, and especially the switching of the free layer 310 from the P state 302″ to the AP state 302′. Accordingly, this process is more efficient than when switching from the P state to the AP state in the MTJ 100 of FIG. 1 and makes I_{P-AP} in the MTJ stack structure 302 larger than I_{P-AP} in the MTJ 100. Therefore, in the MTJ stack structure 302, I_{P-AP} is closer to I_{AP-P} than in the MTJ 100, thus providing for a reduced write current asymmetry relative to that in the MTJ 100.

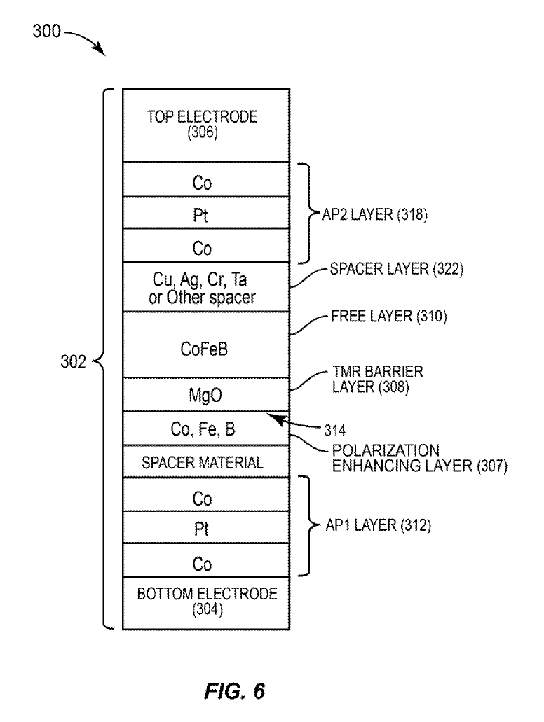

FIG. 6 is a schematic diagram illustrating a detailed stack structure of the exemplary MTJ 300 illustrated in FIG. 3. As discussed earlier, the thicker the material layers that are disposed under the TMR barrier layer 308, the more likely “roughness” will be present at the base 314 of the TMR barrier layer 308. Because the TMR barrier layer 308 is a relatively thin layer (e.g., 5-10 angstroms), any roughness at the base 314 may degrade the functionality of the exemplary MTJ stack structure 302 illustrated in FIG. 3 by reducing the TMR ratio of the MTJ stack structure 302.

In this regard, the MTJ stack structure 302 includes the AP1 layer 312 and the polarization enhancing layer 307 below the corresponding TMR bather layer 308, and the AP2 layer 318 is provided above the corresponding TMR barrier layer 308. The materials that form the polarization enhancing layer 307 are Cobalt (Co), Iron (Fe), and Boron (B). The materials that form the AP1 layer 312 and the AP2 layer 318 are Cobalt (Co) and Platinum (Pt). In some aspects, the AP1 and AP2 layers 312, 318 may be formed by perpendicular alloys such as Cobalt (Co)/Nickel (Ni), Cobalt (Co)/Palladium (Pd), Cobalt (Co)/Iron (Fe)/Nickel (Ni), Cobalt (Co)/Iron (Fe)/Boron (B), Tantalum (Ta)/Iron (Fe)/Cobalt (Co), Gadolinium (Gd)/Iron (Fe)/Cobalt (Co), other ternary alloys, rare earth materials, etc.

In the MTJ stack structure 302, because fewer materials are deposited under the TMR barrier layer 308, the base 314 of the TMR barrier layer 308 is likely to be less rough than the base 218 of the TMR barrier layer 210 in the MTJ stack structure 202 illustrated in FIG. 2. Thus, the MTJ stack structure 302 is likely to provide a higher TMR ratio than the MTJ stack structure 202 illustrated in FIG. 2.

With continued reference to FIG. 6, the MTJ stack structure 302 further comprises the spacer layer 322, which comprises a conductive material, such as long spin diffusion length metals Copper (Cu), Silver (Ag), Chromium (Cr), or Tantalum (Ta), which are easily etched. The MTJ stack structure 302 further includes the free layer 310, comprising, for example, a combination of Cobalt, Iron, and Boron (CoFeB). However, the disclosure is not so limited, and the free layer 310 may comprise other combinations in which a magnetic orientation therein may be switched through exposure to spin-polarized electrons. The MTJ stack structure 302 further includes the TMR barrier layer 308, which comprises, for example, a combination of Magnesium Oxide (MgO). However, the disclosure is not so limited, and other combinations providing an insulator with magneto-resistance properties when combined with adjacent ferromagnets may be used.

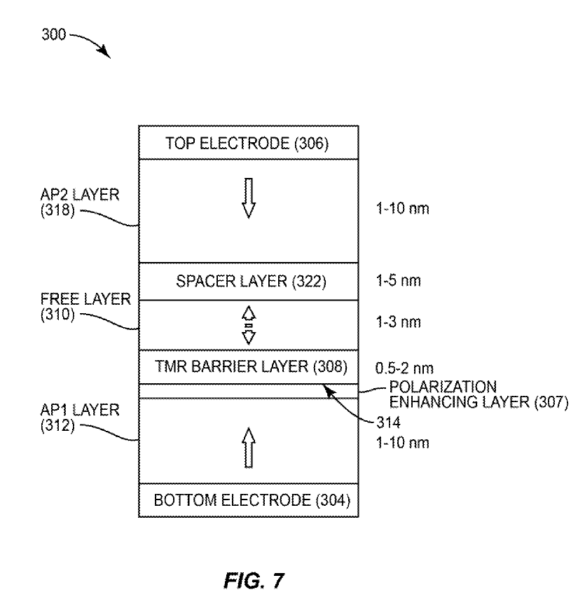

FIG. 7 is a schematic diagram illustrating exemplary dimensions for the exemplary MTJ 300 in FIG. 3. FIG. 7 will be described with reference to FIG. 3. As is illustrated in FIG. 7, in the MTJ 300, each of the AP1 and AP2 layers 312, 318 can have a width of between one (1) and ten (10) nanometers (nm). The TMR barrier layer 308 can have a width of between 0.5 and two (2) nm. The free layer 310 can have a width of between one (1) and three (3) nm. The spacer layer 322 can have a width of between one (1) and five (5) nm. Thus, in exemplary aspects, by providing only the one AP1 layer 312 below the TMR barrier layer 308, the thickness of the material deposited below the TMR barrier layer 308 can be reduced to between one (1) to ten (10) nm. This reduces the probability and/or the degree of roughness at the base 314 of the TMR barrier layer 308, thus increasing the probability of having a high TMR ratio relative to that of a MTJ stack structure such as the MTJ stack structure 202 illustrated in FIG. 2.

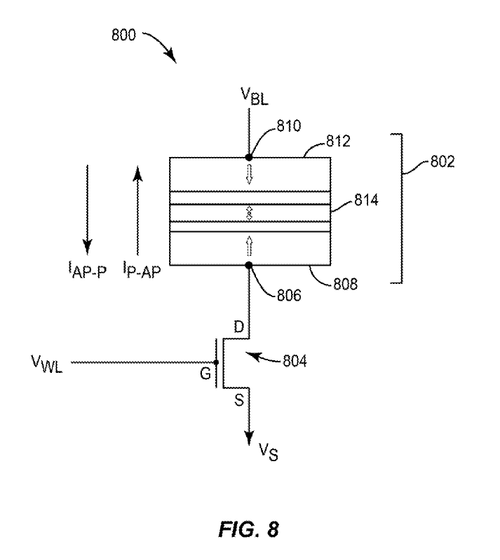

FIG. 8 is a schematic diagram of a MRAM bit cell 800 that includes a MTJ 802 similar to the exemplary MTJ 300 illustrated in FIG. 3. The MRAM bit cell 800 may be provided in a memory array and used as memory storage for any type of system requiring electronic memory, such as a central processing unit (CPU) or processor-based system, as examples. An access transistor 804, which is an n-type metal-oxide semiconductor (NMOS) transistor in this example (referred to hereafter as “NMOS access transistor 804”) is provided to control reading and writing to the MTJ 802. A drain (D) of the NMOS access transistor 804 is coupled to a bottom electrode 806 of the MTJ 802, which is coupled to a first pinned layer 808. A word line (V_{WL}) is coupled to a gate (G) of the NMOS access transistor 804. A source (S) of the NMOS access transistor 804 is coupled to a voltage source (V_{S}). A bit line (V_{BL}) is coupled to a top electrode 810 of the MTJ 802, which is coupled to a second pinned layer 812. A free layer 814 is disposed between the first pinned layer 808 and the second pinned layer 812.

When reading data stored in the MTJ 802, the bit line (V_{BL}) is activated for the NMOS access transistor 804 to allow current to flow through the MTJ 802 between the top and bottom electrodes 810, 806. A low resistance, as measured by voltage applied on the bit line (V_{BL}) divided by the measured current, is associated with a P orientation between the free layer 814 and the net magnetic orientation of the first and second pinned layers 808, 812, i.e., a P state. A higher resistance is associated with an AP orientation between the free layer 814 and the net magnetic orientation of the first and second pinned layers 808, 812, i.e., an AP state. When writing data to the MTJ 802, the gate (G) of the NMOS access transistor 804 is activated by activating the word line (V_{WL}). A voltage differential between the bit line (V_{BL}) and the voltage source (V_{S}) is applied. As a result, a write current (I) (not shown) is generated between the drain (D) and the source (S). If the state of the MTJ 802 is to be changed from AP to P, a write current (I_{AP-P}) flowing from the top electrode 810 to the bottom electrode 806 is generated, which induces a spin-torque-transfer (STT) at the free layer 814 to change the magnetic orientation of the free layer 814 to a P state with respect to the net magnetic orientation of the first and second pinned layers 808, 812. If the state of the MTJ 802 is to be changed from a P state to an AP state, a current (I_{P-AP}) flowing from the bottom electrode 806 to the top electrode 810 is produced, which induces an STT at the free layer 814 to change the magnetic orientation of the free layer 814 to an AP state with respect to the net magnetic orientation of the first and second pinned layers 808, 812.

MTJ devices particularly suited for efficient STT MRAM according to aspects disclosed herein may be provided in or integrated into any processor-based device. Examples, without limitation, include a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

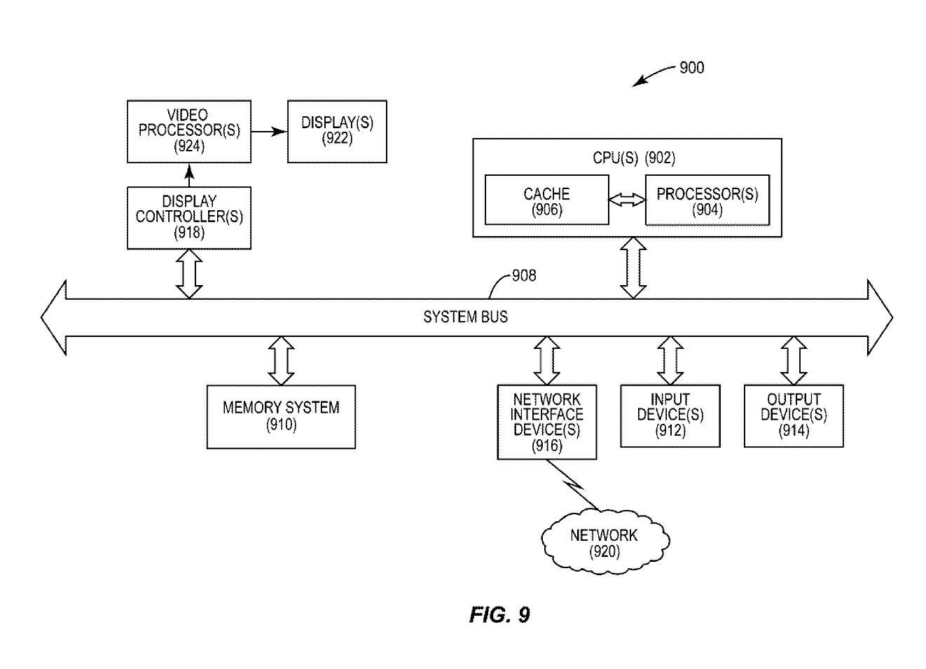

In this regard, FIG. 9 illustrates an example of a processor-based system 900 that can employ a MTJ according to aspects of the disclosure, such as the MTJ 300 illustrated in FIG. 3. In this example, the processor-based system 900 includes one or more CPUs 902, each including one or more processors 904. The CPU(s) 902 may have cache memory 906 coupled to the processor(s) 904 for rapid access to temporarily stored data. The CPU(s) 902 is coupled to a system bus 908 and can intercouple master and slave devices included in the processor-based system 900. As is well known, the CPU(s) 902 communicates with these other devices by exchanging address, control, and data information over the system bus 908. For example, the CPU(s) 902 can communicate bus transaction requests to a memory system 910 as an example of a slave device. Although not illustrated in FIG. 9, multiple system buses 908 could be provided, wherein each system bus 908 constitutes a different fabric.

Other master and slave devices can be connected to the system bus 908. As illustrated in FIG. 9, these devices can include the memory system 910, one or more input devices 912, one or more output devices 914, one or more network interface devices 916, and one or more display controllers 918, as examples. The input device(s) 912 can include any type of input device, including but not limited to input keys, switches, voice processors, etc. The output device(s) 914 can include any type of output device, including but not limited to audio, video, other visual indicators, etc. The network interface device(s) 916 can be any devices configured to allow exchange of data to and from a network 920. The network 920 can be any type of network, including but not limited to a wired or wireless network, a private or public network, a local area network (LAN), a wireless local area network (WLAN), a wide area network (WAN), a BLUETOOTH™ network, and the Internet. The network interface device(s) 916 can be configured to support any type of communications protocol desired.

The CPU(s) 902 may also be configured to access the display controller(s) 918 over the system bus 908 to control information sent to one or more displays 922. The display controller(s) 918 sends information to the display(s) 922 to be displayed via one or more video processors 924, which process the information to be displayed into a format suitable for the display(s) 922. The display(s) 922 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The master devices and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

1. A magnetic tunnel junction (MTJ), comprising:
a first electrode and a second electrode;
a tunnel barrier layer comprising a non-conductive material disposed between the first electrode and the second electrode, the tunnel barrier layer providing a first magneto-resistance between a first pinned layer and a free layer when the first pinned layer is anti-parallel to the free layer;
the first pinned layer disposed between the tunnel barrier layer and the first electrode, the first pinned layer having a first magnetization only in a first direction perpendicular to the first pinned layer;
a second pinned layer disposed between the second electrode and the tunnel barrier layer, the second pinned layer having a second magnetization in a second direction perpendicular to the second pinned layer and that is anti-parallel to the first direction;
the free layer disposed between the second pinned layer and the tunnel barrier layer; and
a spacer layer comprising a conductive material disposed between the second pinned layer and the free layer, the spacer layer providing a second magneto-resistance between the second pinned layer and the free layer when the second pinned layer is anti-parallel to the free layer.

2. The MTJ of claim 1, wherein the tunnel barrier layer comprises Magnesium Oxide (MgO).

3. The MTJ of claim 2, wherein the tunnel barrier layer has a width of between 0.5 and two (2) nanometers (nm).

4. The MTJ of claim 1, wherein the first pinned layer comprises only one magnetic layer, the one magnetic layer comprising Cobalt (Co) and one of Platinum (Pt), Nickel (Ni), and Palladium (Pd).

5. The MTJ of claim 4, wherein the first pinned layer has a width of between one (1) and ten (10) nanometers (nm).

6. The MTJ of claim 1, wherein the first pinned layer comprises only one magnetic layer, the one magnetic layer comprising Cobalt (Co) and Platinum (Pt).

7. The MTJ of claim 6, wherein the first pinned layer has a width of between one (1) and ten (10) nanometers (nm).

8. The MTJ of claim 1, wherein the first pinned layer has a width of between one (1) and ten (10) nanometers (nm).

9. (canceled)

10. The MTJ of claim 9, wherein the conductive material comprises one of Copper (Cu), Silver (Ag), Chromium (Cr), and Tantalum (Ta).

11. The MTJ of claim 1 integrated into an integrated circuit (IC).

12. The MTJ of claim 1 integrated into a device selected from the group consisting of a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

13. A method of forming a magnetic tunnel junction (MTJ), comprising:
providing a first electrode and a second electrode;
placing a tunnel barrier layer comprising a non-conductive material between the first electrode and the second electrode;
placing a first pinned layer having a first magnetization only in a first direction perpendicular to the first pinned layer, between the tunnel barrier layer and the first electrode;
placing a second pinned layer between the second electrode and the tunnel barrier layer having a second magnetization in a second direction perpendicular to the second pinned layer and that is anti-parallel to the first direction;
placing a free layer between the second pinned layer and the tunnel barrier layer; and
placing a spacer layer comprising a conductive material between the second pinned layer and the free layer.

14. The method of claim 13, wherein placing the first pinned layer between the tunnel barrier layer and the first electrode comprises placing at least one material such that the first pinned layer provides the first magnetization in only one direction between the tunnel barrier layer and the first electrode.

15. A magnetic random access memory (MRAM) bit cell, comprising:
an access transistor having a gate, a source, and a drain; and
a magnetic tunnel junction (MTJ), comprising:
a first electrode and a second electrode;
a tunnel barrier layer comprising a non-conductive material disposed between the first electrode and the second electrode, the tunnel barrier layer providing a first magneto-resistance between a first pinned layer and a free layer when the first pinned layer is anti-parallel to the free layer;
the first pinned layer disposed between the tunnel barrier layer and the first electrode, the first pinned layer having a first magnetization only in a first direction perpendicular to the first pinned layer;
a second pinned layer disposed between the second electrode and the tunnel barrier layer, the second pinned layer having a second magnetization in a second direction perpendicular to the second pinned layer and that is anti-parallel to the first direction;
the free layer disposed between the second pinned layer and the tunnel barrier layer; and
a spacer layer comprising a conductive material disposed between the second pinned layer and the free layer, the spacer layer providing a second magneto-resistance between the second pinned layer and the free layer when the second pinned layer is anti-parallel to the free layer,
wherein a word line is coupled to the gate, the second electrode is coupled to the drain, and a bit line is coupled to the first electrode.

16. The MRAM bit cell of claim 15, wherein the tunnel barrier layer comprises Magnesium Oxide (MgO).

17. The MRAM bit cell of claim 16, wherein the tunnel barrier layer has a width of between 0.5 and two (2) nanometers (nm).

18. (canceled)

19. The MRAM bit cell of claim 18, wherein the conductive material comprises one of Copper (Cu), Silver (Ag), Chromium (Cr), and Tantalum (Ta).

20. The MRAM bit cell of claim 15 integrated in at least one semiconductor die.

21. The MRAM bit cell of claim 15 integrated into a device selected from a group consisting of a set top box, an entertainment unit, a navigation device, a communications device, a personal digital assistant (PDA), a fixed location data unit, a mobile location data unit, a mobile phone, a cellular phone, a computer, a portable computer, a desktop computer, a monitor, a computer monitor, a television, a tuner, a radio, a satellite radio, a music player, a digital music player, a portable music player, a video player, a digital video player, a digital video disc (DVD) player, and a portable digital video player.

22. A magnetic tunnel junction (MTJ), comprising:
a first electrode and a second electrode;
a tunnel barrier layer disposed between the first electrode and the second electrode, the tunnel barrier layer comprising Magnesium Oxide (MgO);
a first pinned layer disposed between the tunnel barrier layer and the first electrode, the first pinned layer comprising Cobalt (Co) and at least one of Platinum (Pt), Nickel (Ni), and Palladium (Pd), and providing a first magnetization only in a first direction perpendicular to the first pinned layer, between the tunnel barrier layer and the first electrode;
a second pinned layer disposed between the second electrode and the tunnel barrier layer, the second pinned layer providing a second magnetization in a second direction perpendicular to the second pinned layer and that is anti-parallel to the first direction; and
a free layer disposed between the second pinned layer and the tunnel barrier layer, the free layer comprising Cobalt (Co), Iron (Fe), and Boron (B).

23. The MTJ of claim 22, wherein the tunnel barrier layer has a width of between 0.5 and two (2) nanometers (nm).

24. The MTJ of claim 22, further comprising a spacer layer disposed between the second pinned layer and the free layer, the spacer layer providing a magneto-resistance between the second pinned layer and the free layer when the second pinned layer is anti-parallel to the free layer, the spacer layer comprising a conductive material.

25. The MTJ of claim 24, wherein the conductive material comprises one of Copper (Cu), Silver (Ag), Chromium (Cr), and Tantalum (Ta).

26. The MTJ of claim 23, wherein the first pinned layer has a width of between one (1) and ten (10) nanometers (nm).

27. The MTJ of claim 1, wherein:
the tunnel barrier layer provides a tunneling magneto-resistance (TMR) between the first pinned layer and the free layer when the first pinned layer is anti-parallel to the free layer; and
the spacer layer provides a giant magneto-resistance (GMR) between the second pinned layer and the free layer when the second pinned layer is anti-parallel to the free layer.

28. The MTJ of claim 1, wherein the tunnel barrier layer provides the first magneto-resistance when the first pinned layer is anti-parallel to the free layer as a higher magneto-resistance than the second magneto-resistance of the spacer layer when the second pinned layer is anti-parallel to the free layer.

29. The method of claim 13, wherein:
the tunnel barrier layer provides a tunneling magneto-resistance (TMR) between the first pinned layer and the free layer when the first pinned layer is anti-parallel to the free layer; and
the spacer layer provides a giant magneto-resistance (GMR) between the second pinned layer and the free layer when the second pinned layer is anti-parallel to the free layer.

30. The method of claim 13, wherein the tunnel barrier layer provides a first magneto-resistance when the first pinned layer is anti-parallel to the free layer as a higher magneto-resistance than the second magneto-resistance of the spacer layer when the second pinned layer is anti-parallel to the free layer.

31. The MRAM bit cell of claim 15, wherein:
the tunnel barrier layer provides a tunneling magneto-resistance (TMR) between the first pinned layer and the free layer when the first pinned layer is anti-parallel to the free layer; and
the spacer layer provides a giant magneto-resistance (GMR) between the second pinned layer and the free layer when the second pinned layer is anti-parallel to the free layer.

32. The MRAM bit cell of claim 15, wherein the tunnel barrier layer provides the first magneto-resistance when the first pinned layer is anti-parallel to the free layer as a higher magneto-resistance than the second magneto-resistance of the spacer layer when the second pinned layer is anti-parallel to the free layer.

33. The MTJ of claim 22, wherein the tunnel barrier layer comprises a non-conductive material.
